(19) United States
(12) Patent Application Publication
(10) Pub. No.: US 2004/0005772 A1
(43) Pub. Date: Jan. 8, 2004

(54) Method of producing copper foil solder bump

(76) Inventors: Chang-hee Choi, Kyunggi-do (KR); Sang-yum Kim, Kyunggi-do (KR); Cha-Je Cho, Kyunggi-do (KR)

Correspondence Address: CHRISTINE, PARKER & HALE, LLP, P. O. BOX 7068, PASADENA, CA, 91109-7068, US

(21) Appl. No.: 10/434,410

(22) Filed: May 8, 2003

(30) Foreign Application Priority Data
May 9, 2002 (KR) 2002-25648

(51) Int. Cl. H01L 21/44

(52) U.S. Cl. 438/614; 438/615; 438/687

(57) ABSTRACT

The present invention discloses a method of producing a copper foil used for a printed circuit board (PCB). In this method of producing a copper foil for a solder bump, metal surfaces are activated by plasma or primer treatment and finally are clad using a pressing means in a process of cladding a copper foil constituting a bump and a copper foil forming a circuit. Therefore, it is possible to produce a copper foil for a PCB with excellent adhesion strength without carrying out any bump forming process.

### BACKGROUND OF THE INVENTION

1. Field of the Invention

The present invention relates to a method of producing a copper foil used for a printed circuit board (PCB), and more specifically, to a method of producing a copper foil used in a PCB, capable of producing a copper foil for a PCB with excellent adhesive strength without any bumps in the forming process by contacting metal surfaces with a plasma or primer treatment and finally, cladding them using a pressing means in a process of cladding a copper foil constituting a bump and a copper foil forming a circuit.

2. Description of the Related Art

In general, a PCB is referred to as a printed circuit board in which several parts of various kinds are closely arranged on a flat plate made of phenol resin or epoxy resin and a circuit linking the parts, and is compacted and fixed on the surface of the resin flat plate.

Such a PCB is made in such a manner that a required circuit is constructed by attaching a sheet of copper or the like on one face of a phenol resin insulating board or epoxy resin insulating board, and then etching it along the wiring pattern of the circuit. (removing it by corrosion excepting the circuit on the lines). Then holes for mounting parts are perforated.

Recently, as communication equipment and electronic products are becoming more miniaturized and thinner, PCBs used as a substrate circuit are also being multi-layered and thinned in order to increase the level of integrity. To meet this trend, new techniques including a build-up method have been recently developed. However, they are limited when considering the techniques used and price of forming micro via holes and fine patterns which are becoming finer and finer.

To overcome such limits, in a PCB production process, especially, in a laser drilling process, copper plating process and image patterning process, there is an urgent need for developing an innovative technique and the facilities for this technique. For this purpose, as one of recently developed techniques, there is a method of producing a bump by cladding two copper sheets and then etching one face.

In this bump production method, one of the two sheets is formed as a bump for attaching an outer lead or something while the other acts as a circuit for electric wiring.

To form the bump, only one face of the two sheets clad has to be etched. At this time, to avoid the etching of the copper foil layer serving as the electric wiring, there must be an etching stop layer between the two sheets.

In a commonly used copper foil for a bump, the thickness of a bump layer ranges from 10 to 200 μm, the thickness of a wiring circuit layer ranges from 1 to 100 μm and the thickness of a stop layer ranges from 0.1 to 10 μm.

As one prior known art, Japanese Patent Laid-Open No. H3-148856 discloses production of lead frames by etching a three-layered lead frame material comprising two metal layers of different thicknesses and an aluminum etching stop layer in between.

The etching stop layer of the three-layered lead frame material used in the method, however, is an aluminum layer formed by vapor deposition. The vapor deposition for forming the aluminum layer disadvantageously requires a complicated process, which increases the production cost of the lead frame material.

As another prior known art, Korean Patent Laid-Open No. 2000-0068907 and U.S. Pat. No. 6,177,566 disclose production of a nickel-phosphorus alloy as an etching stop layer by electroplating. Namely, they disclose a method that at least one metal selected from Si, Ni, Zn, P, Fe, Zr, Cr, and Mg and alloys thereof are used as an etching stop layer, a nickel-phosphorus layer is formed on the surface of a copper sheet and then copper is plated on the resulting surface.

However, this method was problematic in that the adhesive force between the nickel-phosphorus layer and the copper plated thereon is low and it is difficult to carry out continuous plating.

### SUMMARY OF THE INVENTION

To solve the above-indicated problems, it is, therefore, an object of the present invention to provide a method of producing a copper foil for a bump which improves adhesion strength by a batch process of plasma treatment and pressing treatment on a copper foil coated with a nickel stop layer and a copper foil coated with no nickel stop layer, not by manufacturing a copper foil layer on the copper foil coated with a nickel stop layer through copper coating as in the conventional art.

To achieve the above object, there is provided a method of producing a copper foil for a solder bump, comprising the steps of: coating a first copper foil with a stop layer; charging the first copper foil and a second copper foil coated with a no stop layer into a vacuum chamber; passing the first and second copper foils charged into the vacuum chamber through a plasma treatment tank; and cladding the first and second copper foils that have passed through the plasma treatment tank by a pressing means.

Preferably, the step of applying a primer is done before the step of charging the first and second copper foils into the vacuum chamber.

At this time, the pressing means preferably is a rolling mill or a press.

### BRIEF DESCRIPTION OF THE DRAWINGS

The above objects, features and advantages of the present invention will become more apparent from the following detailed description when taken in conjunction with the accompanying drawings, in which:

FIG. 1 is a view illustrating a process of cladding a copper foil in accordance with the present invention;

FIG. 2 is a flow chart showing a process of producing a copper foil in accordance with one embodiment of the present invention; and

FIG. 3 is a flow chart showing a process of producing a copper foil in accordance with another embodiment of the present invention;

### DETAILED DESCRIPTION OF THE PREFERRED EMBODIMENT

Preferred embodiments of the present invention will now be described in detail with reference to the accompanying drawings.

Before describing the embodiments of the present invention, the terms and words used in the specification and claims must not be interpreted in their usual or dictionary sense, but are to be interpreted as broadly as is consistent with the technical thoughts of the invention disclosed herein based upon the principle that the inventor can define the concepts of the terms properly in order to explain the invention in the best way.

Accordingly, the embodiments described in this specification and the construction shown in the drawings are nothing but one preferred embodiment of the present invention, and it does not cover all the technical ideas of the invention. Thus, it should be understood that various changes and modifications may be made upon the point of time of this application.

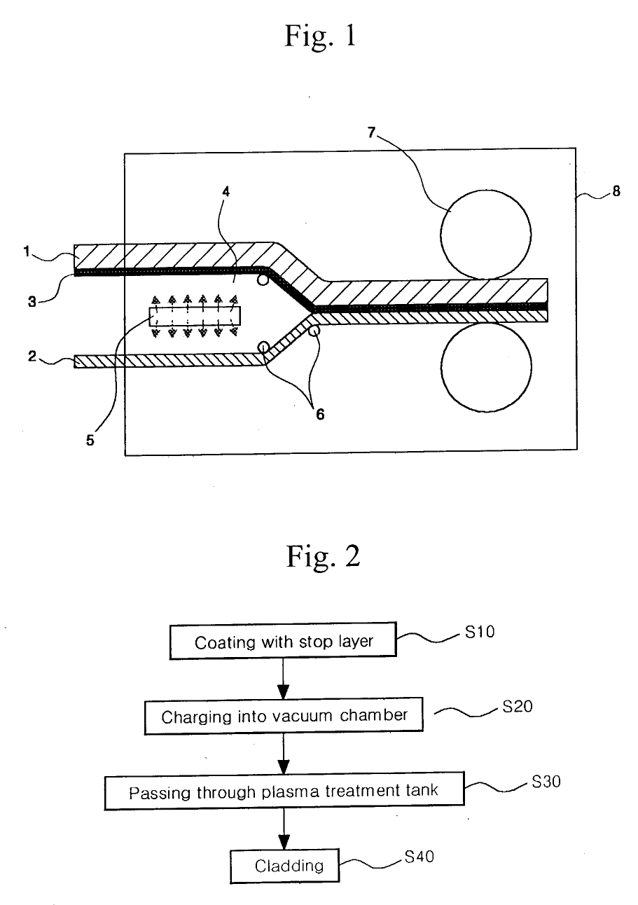

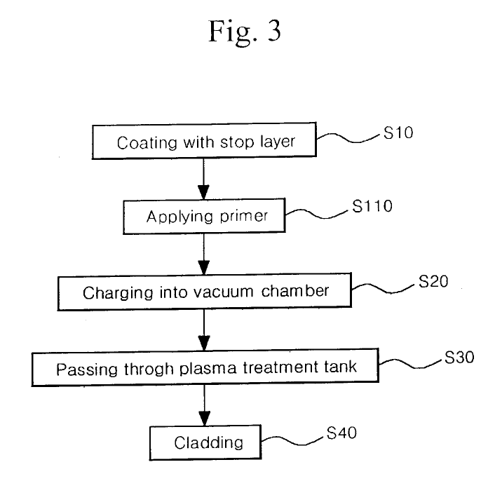

FIG. 1 is a view illustrating a process of cladding a copper foil in accordance with the present invention. FIG. 2 is a flow chart showing a process of producing a copper foil in accordance with one embodiment of the present invention. FIG. 3 is a flow chart showing a process of producing a copper foil in accordance with another embodiment of the present invention.

Firstly, as shown in FIGS. 1 and 2, in the method of producing a copper foil for a solder bump in accordance with one embodiment of the present invention, metal surfaces of a first copper foil coated with a stop layer and a second copper foil coated with no stop layers are activated by plasma treatment, thereby improving the adhesion force when cladding the copper foils.

At this time, the first coil and the second copper foil are separated according to whether they are coated with a stop layer or not, so the first and second copper foils can be either a bump layer or wiring circuit layer.

The present invention will be described more concretely. First, a first copper foil 1 is coated with a stop layer 3 and a second copper foil 2 is not coated with the stop layer 3 in step S10.

Next, the first copper foil 1 and the second copper foil 2 are charged into a vacuum chamber 8 in a step S20. At this time, the vacuum chamber 8 is provided therein with a plasma treatment tank 4 with a plasma generator 5, a plurality of support rolls 6 for converging the separately moving copper foils 1 and 2 and pressing means for compressing and cladding the moving copper foils 1 and 2 that are converged.

The first and second copper foils 1 and 2 charged into the thus-constructed vacuum chamber 8 pass through the plasma treatment tank 4, being spaced apart from each other in a step S30. At this time, the plasma generated from the plasma generator 5 mounted within the plasma treatment tank 4 penetrates into the surfaces of the first and second copper foils 1 and 2.

Meanwhile, plasma can be defined as a completely or partially ionized gas composed of ions and electrons. That is, if an electric field of enough size is acted on the gas, the plasma is formed when the gas is decomposed and ionized into ions and electrons.

The production of the plasma is initiated by free electrons. Here, the free electrons are emitted and generated from a negatively biased electrode, resulting in kinetic energy. The free electrons lose their energy while passing through the gas as they collide with gas molecules. At this time, the energy produced by the collision ionizes the gas molecules.

Next, the electrons emitted in order to get kinetic energy in a working electric field, and this procedure is repeated continuously.

Therefore, the voltage applied among the electrodes in the vacuum chamber 8 reaches a discharge potential, continuous plasma is produced. As a plasma apparatus, it is preferable to use an apparatus that forms a uniform and stable plasma discharge and forms a plasma discharge at an ambient temperature and at an atmospheric pressure.

That is to say, using a special discharge system, the production of plasma can be implemented at a temperature of as low as 150° C. at an ambient temperature. The gases used for producing plasma include nitrogen, oxygen, ammonia, methane, ethylene and the like.

The plasma generator 5 according to the present invention gets a voltage of 1 to 100 kV by a power supply, whereby the vacuum chamber 8 are charged with an anode and the first and second copper foils 1 and 2 are charged with a cathode. The gases injected into the vacuum chamber 8 collide with the electrons emitted from the electrodes connected to an auxiliary power source and becomes a plasma state.

Therefore, while the first and second copper foils 1 and 2 pass through the vacuum chamber 8, plasma positive ions penetrate into the surfaces of the first and second copper foils 1 and 2 of the cathode by an electric potential difference.

Since such a plasma treatment is superior in mass transfer to other methods, the plasma positive ions can be uniformly penetrated without being affected by the surface structure of the copper foils.

Additionally, the thus treated surfaces of the copper foils are not abraded well and have a firm surface structure. Also, since the metal surfaces can be changed between hydrophilic and hydrophobic, the residual moisture on the copper foil surfaces before adhesion can be easily adjusted. Besides, they are resistant to a corrosive environment.

While, the first and second copper foils 1 and 2 that have passed through the plasma treatment tank 4 are clad by the pressing means 7, thereby completing a copper foil for a solder bump in a step S40.

At this time, the pressing means used is a rolling mill 7 or a press. Here, it is effective that the rolling mill 7 applies a pressure that is enough to get an adhesive force without creating a large deformation of the two copper foils 1 and 2. Preferably, a coiler and uncoiler for preventing the deflection of the coils are attached to the front and rear ends of the rolling mill 7.

In another embodiment of the present invention, as shown in FIG. 3, after the step S10 of coating the first copper coil 1 with the stop layer 3 and coating the second copper foil 2 with no stop layer 3 and before the step S20 of charging the first and second copper foils 1 and 2 into the vacuum chamber 8, the step of applying a primer on the surfaces of the first and second copper foils 1 and 2 is further included, whereby the adhesion strength of the first and second copper foils 1 and 2 is improved.

Table 1 is a comparison between the cladding strength of the copper foil according to the present invention and the cladding strength of the conventional copper foil.

TABLE 1

| | Adhesion Strength (kg/cm) | | Rate of decrease |
|---|---|---|---|
| | Before heat | After heat | of adhesion |
| Classification | treatment | treatment | strength (%) |
| Embodiment | 10 | 10 | 0 |
| Comparative | 5 | 4.8 | 20 |
| Example 1 | | | |
| Comparative | 3 | 1 | 30 |
| Example 2 | | | |

As seen in Table 1, among the conventional copper foils for a bump which did not undergo plasma treatment, the strongly rolled one (Comparative Example 1) and the weakly rolled one (Comparative Example 2) showed a decrease in adhesion strength by 20% and 30% respectively after heat treatment, while the copper foil for a bump (Embodiment) according to the present invention is superior in adhesion strength to the Comparative Examples and its adhesion strength does not decrease even after heat treatment or chemical treatment.

As described above, the method of producing the copper foil for the solder bump according to the present invention can improve the adhesion strength by performing a stop layer treatment on the first copper foil and plasma or primer treatment on the first and second copper foils.

What is claimed is:

1. A method of producing a copper foil for a solder bump, comprising the steps of:
coating a first copper foil with a stop layer;
charging the first copper foil and a second copper foil coated with no stop layer into a vacuum chamber;
passing the first and second copper foils charged into the vacuum chamber through a plasma treatment tank; and
cladding the first and second copper foils that have passed through the plasma treatment tank by a pressing means.

2. The method of claim 1, further comprising the step of applying a primer before the step of charging the first and second copper foils into the vacuum chamber.

3. The method of claim 1, wherein the pressing means is a rolling mill or a press.
